(19) United States
(12) Patent Application Publication
(10) Pub. No.: US 2020/0058886 A1
(43) Pub. Date: Feb. 20, 2020

(54) METHOD FOR PREPARING FLEXIBLE OLED DISPLAY PANEL AND MOTHERBOARD STRUCTURE THEREOF

(71) Applicant: Wuhan China Star Optoelectronics Semiconductor Display Technology Co., Ltd., Wuhan (CN)

(72) Inventor: Chaoyu YUAN, Wuhan (CN)

(73) Assignee: Wuhan China Star Optoelectronics Semiconductor Display Technology Co., Ltd., Wuhan (CN)

(21) Appl. No.: 16/281,098

(22) Filed: Feb. 21, 2019

(30) Foreign Application Priority Data
Aug. 14, 2018 (CN) 201810919562.4

(51) Int. Cl. H01L 51/00; H01L 27/32; H01L 51/52; H01L 51/56

(52) U.S. Cl. CPC H01L 51/0097; H01L 51/56; H01L 51/5253; H01L 27/3244

(57) ABSTRACT

A method for preparing a flexible OLED display panel and the motherboard structure thereof are provided. The method includes disposing a first protective film on a second surface of the support substrate. A projection of the first protective film on the flexible OLED motherboard covers each of the flexible OLED display panels so that the support substrate can be prevented from being scratched during the substrate transfer process. In addition, it is unnecessary to grind and clean the support substrate in the laser lift-off process, thereby optimizing the production process, improving the production efficiency and reducing the production cost.

### RELATED APPLICATIONS

This application claims the benefit of priority of Chinese Patent Application No. 201810919562.4 filed on Aug. 14, 2018, the contents of which are incorporated herein by reference in their entirety.

### FIELD AND BACKGROUND OF THE INVENTION

The present invention relates to the field of display technologies and specifically relates to a method for preparing a flexible OLED (organic light emitting diode) display panel and a motherboard structure of the flexible OLED display.

The organic light-emitting diodes (OLEDs) have a lot of excellent characteristics such as self-luminous, low power consumption, wide viewing angle, rich in color, fast response and an availability of preparing flexible screen, which arouse great interest in academia and industry and are considered to be a promising likely next-generation display technology. The flexible OLED display panel is one of important development trends of the OLEDs.

Each process in the preparation of a flexible OLED display panel directly affects its usage performance. The laser lift-off process is a particularly key process for separating a support substrate and a flexible substrate by the effect of laser. The laser passes through a support substrate to break the hydrogen bonding force between the support substrate and the flexible substrate to effectively separate the support substrate from the flexible substrate. However, before the laser lift-off, the surface of a support substrate must be ground and cleaned to remove the dirt and the residual glue on the surface of the support substrate, thereby preventing the influence on the pass-through of laser energy in the laser lift-off process, which may result in poor lift-off. In the current production of the flexible OLED display panels, the back side of the support substrate may be scratched during the substrate transfer process. Moreover, the glass may be inevitably scratched during the grinding and cleaning process, thereby, influencing the pass-through of laser energy during the laser lift-off, which may result in poor lift-off, so that the product yield is reduced. Therefore, the prior art has drawbacks and is urgent to be improved.

### SUMMARY OF THE INVENTION

An object of the present invention is to provide a method for preparing a flexible OLED display panel and the motherboard structure thereof, which can prevent the support substrate from being scratched during the substrate transfer process, thereby improving the production efficiency and reducing the production cost.

The invention provides a motherboard structure of a flexible OLED display panel, which includes:

a support substrate, the support substrate includes the oppositely disposed first surface and second surface; a flexible OLED motherboard, the flexible OLED motherboard being disposed on the first surface, and the flexible OLED motherboard includes a plurality of flexible OLED display panels arranged at intervals from each other; and

a first protective film, the first protective film being disposed on the second surface; wherein a projection of the first protective film on the flexible OLED motherboard covers each of the flexible OLED display panels.

In the motherboard structure of the flexible OLED display panel of the present invention, the first protective film includes a plurality of first sub-protective films arranged at intervals from each other, each of the first sub-protective films corresponds to each of the flexible OLED display panels.

In the motherboard structure of the flexible OLED display panel of the present invention, an area of the first sub-protective film is larger than an area of its corresponding flexible OLED display panel.

In the motherboard structure of the flexible OLED display panel of the present invention, the second surface is provided with a cutting line, and the cutting line is exposed from the second surface.

In the motherboard structure of the flexible OLED display panel of the present invention, the flexible OLED motherboard includes:

a flexible substrate, a thin film transistor array layer, an anode layer, an organic light-emitting layer, a cathode layer, and an encapsulation layer, which are sequentially laminated on the first surface.

In the motherboard structure of the flexible OLED display panel of the present invention, the flexible OLED motherboard on which a second protective film is further provided with, and the second protective film covers the flexible OLED motherboard.

In the motherboard structure of the flexible OLED display panel of the present invention, a thickness of the first protective film is between 30 micrometers and 50 micrometers.

In the motherboard structure of the flexible OLED display panel of the present invention, a material of the first protective film is polyethylene terephthalate.

The invention further provides a method for preparing a flexible OLED display panel, including:

preparing a motherboard structure of the flexible OLED display panel, the motherboard structure of the display panel of the flexible OLED including a support substrate, the support substrate including the oppositely disposed first surface and second surface; a flexible OLED motherboard, the flexible OLED motherboard being disposed on the first surface, the flexible OLED motherboard including a plurality of flexible OLED display panels arranged at intervals from each other; a first protective film, the first protective film being disposed on the second surface; wherein a projection of the first protective film on the flexible OLED motherboard covers each of the flexible OLED display panels; cutting the motherboard structure of the flexible OLED display panel so that the support substrate, the flexible OLED motherboard, and the first protective film are cut to obtain a single piece of the flexible OLED display panel; removing the first protective film and cleaning the first surface; irradiating the support substrate with a laser to lift off the support substrate from the flexible OLED display panel.

In the method for preparing a flexible OLED display panel of the present invention, the first protective film includes a plurality of first sub-protective films arranged at intervals from each other, each of the first sub-protective films corresponds to each of the flexible OLED display panels.

The steps of the preparation of the flexible OLED display panel including:

providing a support substrate and forming a cutting line in the second surface of the support substrate; forming a flexible OLED motherboard on the first surface of the support substrate; adopting the chemical-based vapor deposition method or the physical-based vapor deposition method to form a first protective film on the second surface of the support substrate.

The method for preparing a flexible OLED display panel and the motherboard structure thereof of the present invention, by disposing a first protective film on a second surface of the support substrate, a projection of the first protective film on the flexible OLED motherboard covers each of the flexible OLED display panels so that the support substrate can be prevented from being scratched during the substrate transfer process; in addition, it is unnecessary to grind and clean the support substrate in the laser lift-off process, thereby optimizing the production process, improving the production efficiency and reducing the production cost.

### BRIEF DESCRIPTION OF THE SEVERAL VIEWS OF THE DRAWINGS

In order to more clearly illustrate the technical solutions in the embodiments of the present invention, the following figures described in the embodiments will be briefly introduced. It is obvious that the drawings described below are merely some embodiments of the present invention, other drawings can also be obtained by the person ordinary skilled in the field based on these drawings without doing any creative activity.

FIG. 1 is a schematic view illustrating a motherboard structure of a flexible OLED display panel according to an embodiment of the present invention.

FIG. 2 is a cross-sectional view taken along line A-A in FIG. 1, illustrating the motherboard structure of the flexible OLED display panel.

FIG. 3 is a schematic flowchart illustrating a method for preparing a flexible OLED display panel according to the embodiment of the present invention.

FIG. 4 is a schematic flowchart regarding the preparation of the motherboard structure of the flexible OLED display panel in FIG. 3.

### DESCRIPTION OF SPECIFIC EMBODIMENTS OF THE INVENTION

The technical solutions in the embodiments of the present invention will be clearly and completely described as follows with reference to the drawings in the embodiments of the present invention. Obviously, the described embodiments are a part of the embodiments in the invention, not all of them. Based on the embodiments of the present invention, all other embodiments obtained by those skilled in the field without doing any creative activity are within the claimed scope of the present invention.

In the description of the present invention, the terms “first” and “second” are used for descriptive purpose only and are not to be construed as indicating or implying a relative importance or implicitly indicating the number of the specified technical features. Thus, the features defining “first” or “second” may include one or more described features either explicitly or implicitly. In the description of the present invention, the meaning of “a plurality of” denotes two or more unless it is otherwise specifically stated.

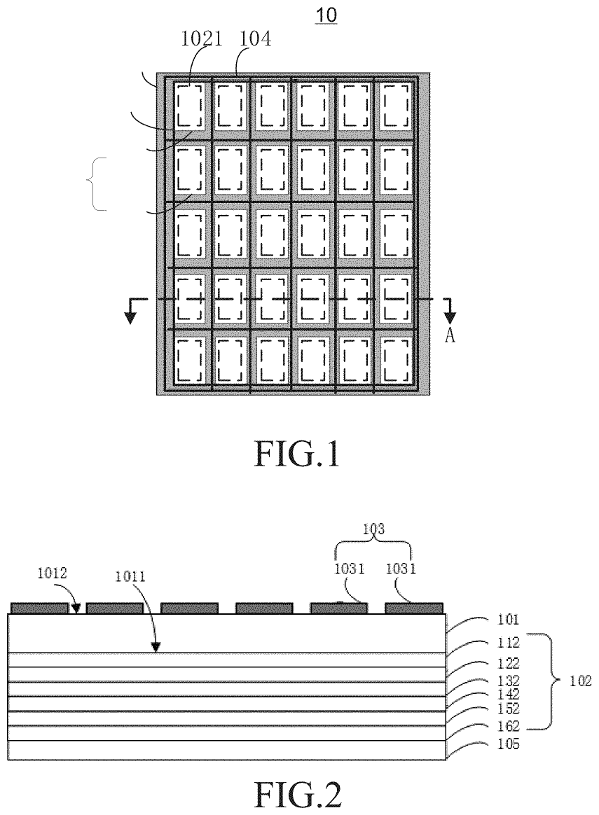

Please refer to FIG. 1 and FIG. 2; FIG. 1 is a schematic view illustrating a motherboard structure of a flexible OLED display panel according to an embodiment of the present invention; FIG. 2 is a cross-sectional view taken along line A-A in FIG. 1, illustrating the motherboard structure of the flexible OLED display panel. As shown in FIG. 1 and FIG. 2, the motherboard structure 10 of the flexible OLED display panel of the embodiment of the present invention includes a support substrate 101, a flexible OLED motherboard 102 and a first protective film 103; the support substrate 101 includes the oppositely disposed first surface 1011 and second surface 1012. A flexible OLED motherboard 102 is disposed on the first surface 1011. The flexible OLED motherboard 102 includes a plurality of flexible OLED display panels 1021 arranged at intervals from each other. A first protective film 103 is disposed on the second surface 1012, and a projection of the first protective film 103 on the flexible OLED motherboard 102 covers each of the flexible OLED display panels 1021.

It should be noted that the motherboard structure 10 of the flexible OLED display panel of the embodiment in the present invention may form the plurality of flexible OLED display panels 1021 by cutting, lift-off, or the like processes. For example, the motherboard structure 10 of the flexible OLED display panel can form the plurality of flexible OLED display panels 1021 with the support substrate 101 by a cutting process; and the support substrate 101 is separated from the flexible OLED display panels 1021 by a lift-off process. For another example, the lift-off process may adopt a laser lift-off; that is, the support substrate 101 is separated by the laser irradiation so that the support substrate 101 and the flexible OLED display panels 1021 are separated. In addition, it is necessary to ensure that the surface of the support substrate 101 is clean before the laser lift-off, and to avoid affecting the pass-through of laser energy during the lift-off, which may result in poor lift-off.

The motherboard structure 10 of the flexible OLED display panel in the embodiment of the present invention can ensure that the second surface 1012 of the support substrate 101 is clean by disposing the first protective film 103 on the second surface 1012 of the support substrate 101. Furthermore, the second surface 1012 of the support substrate 101 can be prevented from being scratched during the substrate transfer process, so that it does not affect the pass-through of laser energy during the laser lift-off process, which may result in poor lift-off, thereby improving the product yield.

In some embodiments, the plural flexible OLED display panels 1021 arranged at intervals can be the same specification and size and arranged in a regular array on the flexible OLED motherboard 102, thereby lowering the processing difficulty thereof. In other embodiments, the plural flexible OLED display panels 1021 arranged at intervals can be the flexible OLED display panels 1021 of various specifications and sizes, so that the flexible OLED display panels 1021 of various specifications and sizes can be simultaneously prepared and obtained.

Correspondingly, the first protective film 103 includes a plurality of first sub-protective films 1031 arranged at intervals from each other. Each of the first sub-protective films 1031 corresponds to each of the flexible OLED display panels 1021. For example, when the plural flexible OLED display panels 1021 arranged at intervals are in the same specification and size, the plural first sub-protective films 1031 arranged at intervals are also in the same specification and size and they are arranged in a regular array on the second surface 1012 of the support substrate 101. For another example, when the plural flexible OLED display panels 1021 arranged at interval are in various specifications and sizes, the plural first sub-protective films 1031 arranged at interval are also in various specifications and sizes.

That is, the motherboard structure 10 of the flexible OLED display panel in the embodiment of the present invention is provided with a plurality of the first sub-protective films 1031 on the second surface 1012 of the support substrate 101. The plural first sub-protective films 1031 correspond to the plural OLED display panels 1021. Each of the sub-protective films 1031 serves to ensure that the second surface 1012 of the support substrate 101 on the corresponding flexible OLED display panel 1021 is clean.

Furthermore, a cutting line 104 is disposed in the second surface of the support substrate 101, and the cutting line 104 is exposed from the second surface 1012 of the support substrate 101. The cutting line 104 is a cutting mark disposed in the second surface 1012 of the support substrate 101. When the motherboard structure 10 of the flexible OLED display panel is proceeded with a cutting process to form the plurality of the flexible OLED display panels 1021 with the support substrate 101, the cutting may be carried out along the cutting line 104. That is, the first protective film 103 is disposed on the second surface 1012 of the support substrate 101, and does not block the cutting line 104 provided in the second surface 1012 of the support substrate 101.

In addition, an area of the first sub-protective film 1031 is greater than or equal to an area of the corresponding flexible OLED display panel 1021. By setting the area of the first sub-protective film 1031 to be greater than or equal to the area of the corresponding flexible OLED display panel 1021, the cleanness of the second surface 1012 of the corresponding support substrate 101 of the flexible OLED display panel 1021 can be sufficiently ensured.

In the embodiment of the present invention, the flexible OLED motherboard 102 includes a flexible substrate 112, a thin film transistor array layer 122, an anode layer 132, an organic light-emitting layer 142, a cathode layer 152, and an encapsulation layer 162, which are sequentially laminated on the first surface 1012. The thin film transistor array layer 122 is provided with the structural film layers such as a thin film transistor, a data wire, and a scanning wire. The organic light-emitting layer 142 includes a hole transport functional layer, a light-emitting material layer, an electron transport functional layer and the like, which are formed by the preparation of the organic materials.

The material of the flexible substrate 112 can be polyimide, polycarbonate, polyethersulfone, polyethylene terephthalate, polyethylene naphthalate, polyarylate or glass fiber reinforced plastic; the support substrate 101 is a glass substrate.

In the embodiment of the present invention, in order to further protect the OLED display panel, a second protective film 105 is further disposed on the flexible OLED motherboard 102, and the second protective film 105 covers the flexible OLED motherboard 102.

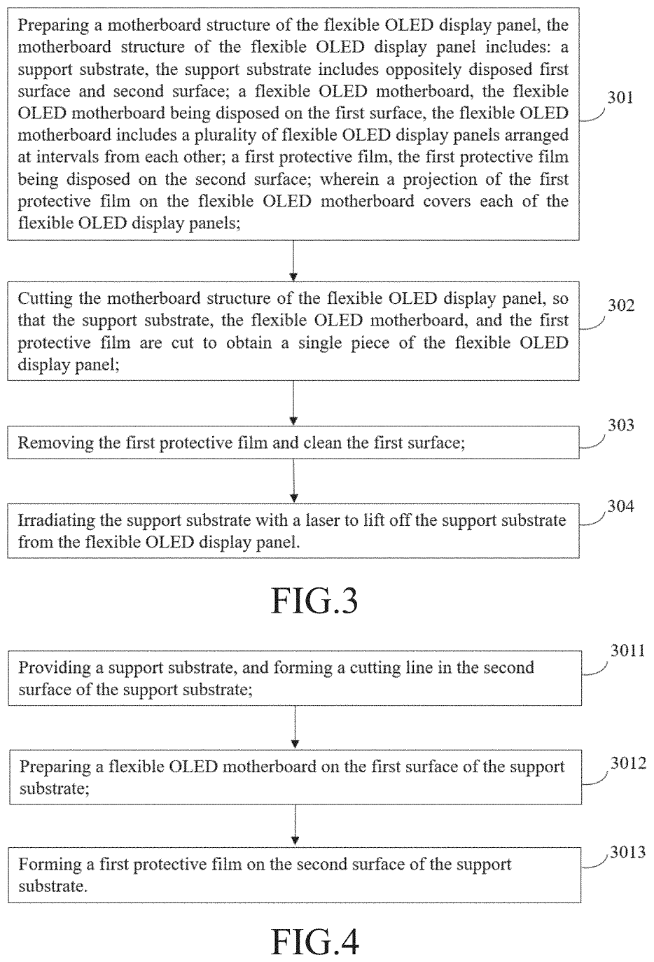

Please refer to FIG. 3; FIG. 3 is a schematic flowchart illustrating a method for preparing a flexible OLED display panel according to the embodiment of the present invention.

As shown in FIG. 3, the method for preparing a flexible OLED display panel according to the present invention includes the following steps:

step 301, preparing the motherboard structure of the flexible OLED display panel, wherein the motherboard structure of the flexible OLED display panel includes a support substrate; the support substrate includes the oppositely disposed first surface and second surface; a flexible OLED motherboard is disposed on the first surface, and the flexible OLED motherboard includes a plurality of the flexible OLED display panels arranged at intervals from each other; a first protective film is disposed on the second surface, wherein a projection of the first protective film on the flexible OLED motherboard covers each of the flexible OLED display panels;

step 302, cutting the motherboard structure of the flexible OLED display panel so that the support substrate, the flexible OLED motherboard, and the first protective film are cut to obtain at least a single piece of the flexible OLED display panel;

step 303, removing the first protective film, and cleaning the first surface; and

step 304, irradiating the support substrate with a laser to lift off the support substrate from the flexible OLED display panel.

In the step 301, the motherboard structure of the flexible OLED display panel can refer to the motherboard structure of the flexible OLED display panel in the embodiment of the present invention as shown in FIG. 1 and FIG. 2, and the details are not described herein.

Please further refer to FIG. 4; FIG. 4 is a schematic flowchart regarding the preparation of a motherboard structure of the flexible OLED display panel in FIG. 3. The step 301 specifically includes: step 3011, providing a support substrate, and forming a cutting line in the second surface of the support substrate, step 3012, preparing a flexible OLED motherboard on the first surface of the support substrate, and step 3013, forming the first protective film on the second surface of the support substrate.

The method for preparing a flexible OLED display panel and the motherboard structure thereof in the present invention, includes disposing a first protective film on a second surface of the support substrate, wherein a projection of the first protective film on the flexible OLED motherboard covers each of the flexible OLED display panels so that the support substrate can be prevented from being scratched during the substrate transfer process. In addition, it is unnecessary to grind and clean the support substrate in the laser lift-off process, thereby optimizing the production process, improving the production efficiency and reducing the production cost.

The method for preparing a flexible OLED display panel and the motherboard structure thereof provided by the embodiments of the present invention are described in detail above, the principles and embodiments of the present invention have been described herein with reference to the exemplary embodiments. The description of the above exemplary embodiments is only for the purpose of understanding the invention. It is to be understood that the present invention is not limited to the disclosed exemplary embodiments. It is obvious to those skilled in the art that the above exemplary embodiments may be modified without departing from the scope and spirit of the present invention.

The description of the above exemplary embodiments is only for the purpose of understanding the invention. It is to be understood that the present invention is not limited to the disclosed exemplary embodiments. It is obvious to those skilled in the art that the above exemplary embodiments may be modified without departing from the scope and spirit of the present invention.

What is claimed is:

1. A motherboard structure of a flexible OLED display panel, comprising:
a support substrate, said support substrate comprising the oppositely disposed first surface and second surface;
a flexible OLED motherboard, said flexible OLED motherboard being disposed on said first surface, said flexible OLED motherboard comprising a plurality of flexible OLED display panels arranged at intervals from each other; and
a first protective film, said first protective film being disposed on said second surface; wherein a projection of said first protective film on said flexible OLED motherboard covers each of said flexible OLED display panels.

2. The motherboard structure of the flexible OLED display panel according to claim 1, wherein said first protective film comprises a plurality of first sub-protective films arranged at intervals from each other, and each of said first sub-protective films corresponds to each of said flexible OLED display panels.

3. The motherboard structure of the flexible OLED display panel according to claim 2, wherein an area of said first sub-protective film is larger than an area of the corresponding flexible OLED display panel.

4. The motherboard structure of the flexible OLED display panel according to claim 3, wherein said second surface is provided with a cutting line, and said cutting line is exposed from said second surface.

5. The motherboard structure of the flexible OLED display panel according to claim 1,
wherein said flexible OLED motherboard comprises:
a flexible substrate, a thin film transistor array layer, an anode layer, an organic light-emitting layer, a cathode layer, and an encapsulation layer, which are sequentially laminated on said first surface.

6. The motherboard structure of the flexible OLED display panel according to claim 5, wherein a second protective film is further disposed on said flexible OLED motherboard, and said second protective film covers said flexible OLED motherboard.

7. The motherboard structure of the flexible OLED display panel according to claim 1, wherein a thickness of said first protective film is between 30 micrometers and 50 micrometers.

8. The motherboard structure of the flexible OLED display panel according to claim 1, wherein a material of said first protective film is polyethylene terephthalate.

9. A method for preparing a flexible OLED display panel, comprising:
preparing a motherboard structure of the flexible OLED display panel, the motherboard structure of said flexible OLED display panel comprising: a support substrate, said support substrate comprising the oppositely disposed first surface and second surface, a flexible OLED motherboard, said flexible OLED motherboard being disposed on said first surface, said flexible OLED motherboard comprising a plurality of flexible OLED display panels arranged at intervals from each other, a first protective film, said first protective film being disposed on said second surface, wherein a projection of said first protective film on said flexible OLED motherboard covers each of said flexible OLED display panels;
cutting the motherboard structure of said flexible OLED display panel, so that said support substrate, said flexible OLED motherboard, and said first protective film are cut to obtain at least a single piece of flexible OLED display panel;
lifting off said first protective film and cleaning said first surface; and
irradiating said support substrate with a laser to lift off said support substrate from said flexible OLED display panel.

10. The method for preparing a flexible OLED display panel according to claim 9, wherein said first protective film comprises a plurality of first sub-protective films arranged at intervals from each other, and each of said first sub-protective film corresponds to each of said flexible OLED display panels, and said step for preparing a motherboard structure of the flexible OLED display panel comprises:
providing the support substrate and forming a cutting line in the second surface of said support substrate;
forming the flexible OLED motherboard on the first surface of said support substrate; and
forming the first protective film on the second surface of said support substrate.

11. The motherboard structure of the flexible OLED display panel according to claim 2, wherein a thickness of said first protective film is between 30 micrometers and 50 micrometers.

12. The motherboard structure of the flexible OLED display panel according to claim 3, wherein a thickness of said first protective film is between 30 micrometers and 50 micrometers.

13. The motherboard structure of the flexible OLED display panel according to claim 4, wherein a thickness of said first protective film is between 30 micrometers and 50 micrometers.

14. The motherboard structure of the flexible OLED display panel according to claim 5, wherein a thickness of said first protective film is between 30 micrometers and 50 micrometers.

15. The motherboard structure of the flexible OLED display panel according to claim 6, wherein a thickness of said first protective film is between 30 micrometers and 50 micrometers.

16. The motherboard structure of the flexible OLED display panel according to claim 2, wherein a material of said first protective film is polyethylene terephthalate.

17. The motherboard structure of the flexible OLED display panel according to claim 3, wherein a material of said first protective film is polyethylene terephthalate.

18. The motherboard structure of the flexible OLED display panel according to claim 4, wherein a material of said first protective film is polyethylene terephthalate.

19. The motherboard structure of the flexible OLED display panel according to claim 5, wherein a material of said first protective film is polyethylene terephthalate.

20. The motherboard structure of the flexible OLED display panel according to claim 6, wherein a material of said first protective film is polyethylene terephthalate.
